(19) United States
(12) Patent Application Publication
(10) Pub. No.: US 2002/0146640 A1
(43) Pub. Date: Oct. 10, 2002

(54) Method of fabricating a printed board

(76) Inventors: Chin Hsi Chen, Chang Hua Hsien (TW); Shin Lung Chen, Chang Hua Hsien (TW)

Correspondence Address: HARRISON & EGBERT, 412 MAIN STREET, 7TH FLOOR, HOUSTON, TX, 77002, US

(21) Appl. No.: 09/828,683

(22) Filed: Apr. 9, 2001

(51) Int. Cl. G03F 7/00

(52) U.S. Cl. 430/270.1; 430/301

(57) ABSTRACT

A printed board fabricating method comprises a first stop in which a blueprint of the printed board is analyzed by an electronic color analyzer so as to enable a computer to process an image composition. The images are then arranged by an image arranging device which is connected with the computer. A PS board is fed into the image arranging device such that the surface of the PS board is provided with a coating of a photoresist agent. The coating is patterned according to the image composition. The coated PS board is then exposed in an exposure device. Finally, the exposed PS board is developed to become the printed board.

### BACKGROUND OF THE INVENTION

1. Field of the Invention

The present invention relates generally to a printed board, and more particularly to a method for fabricating the printed board.

2. Description of Related Art

As illustrated in FIGS. 1-5, a prior art method for making a printed board comprises a first step in which a blueprint is fed into an electronic color analyzer. The images are composed by a computer. The composed images are transferred to a negative output device and then to a negative developing device by which a negative 1 is produced, as shown in FIG. 2. The negative 1 is subsequently attached to an exposure area of a PS board 2 such that the cruciform focus hole of the negative 1 is aligned with the cruciform focus hole of the PS board 2. The exposed area or other exposure area of the PS board 2 is covered with a photomask piece 3, as shown in FIG. 3. The PS board 2 is then introduced into an exposure machine 4, as shown in FIG. 4. Upon completion of the exposure process, the negative 1 is transferred to another exposure area of the PS board 2 such that the cruciform focus hole of the negative 1 is aligned with the cruciform focus hole of the PS board 2. The PS board 2 is then once again put into the exposure machine 4. This process is carried out repeatedly such that the PS. board 2 is provided with a plurality of the exposured areas. The exposed PS board 2 is developed such that the images of the blueprint are printed on the PS board 2, as shown in FIG. 5.

The prior art method described above is not cost-effective in view of the fact that the prior art method makes use of expensive devices, such as the negative output device and the negative developing device, and that the masking of the PS board with the photomask piece 3 and the alignment of the cruciform focus holes of the negative 1 and the PS board 2 are rather time-consuming.

### BRIEF SUMMARY OF THE INVENTION

It is the primary objective of the present invention to provide a method of fabricating a printed board without the use of the negative.

It is another objective of the present invention to provide a cost-effective method of fabricating a printed board.

The objectives and the features of the present invention will be readily understood upon a thoughtful deliberation of the following detailed description of the present invention in reference to the accompanying drawings.

### BRIEF DESCRIPTION OF THE SEVERAL VIEWS OF THE DRAWINGS

FIG. 1 shows a process flow diagram of a prior art method for making a printed board.

FIG. 2 shows a schematic view of a negative of the prior art method for making a printed board.

FIG. 3 shows a schematic view of the PS board, the negative, and the photomasks of the prior art method for making a printed board.

FIG. 4 shows a schematic view of the exposure process of the prior art method for making a printed board.

FIG. 5 shows a perspective view of a printed board made by the prior art method.

FIG. 6 shows a process flow diagram of a method of the present invention for fabricating a printed board.

FIG. 7 shows a perspective view of a PS board processed by the image arranging device of the method of the present invention.

FIG. 8 shows a schematic view of the exposure process of the method of the present invention.

FIG. 9 shows a perspective view of a printed board fabricated by the method of the present invention.

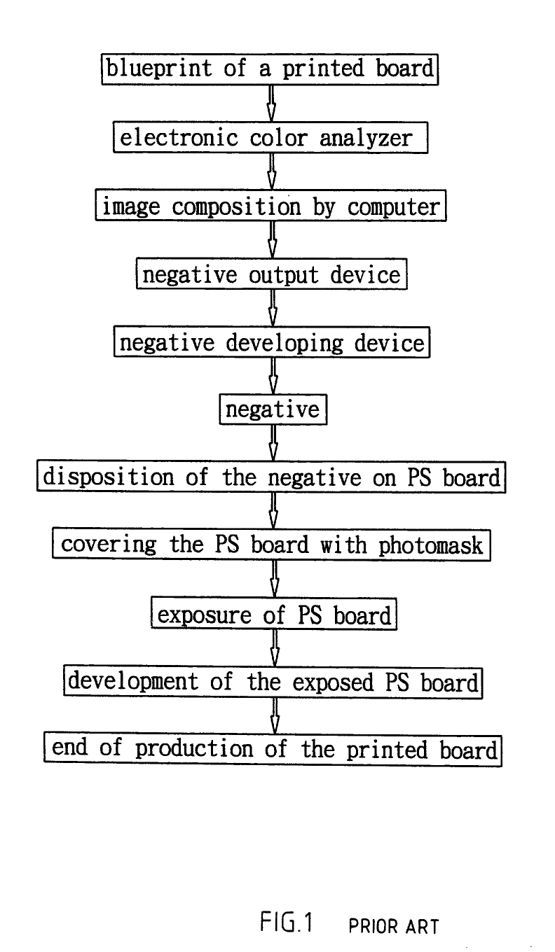

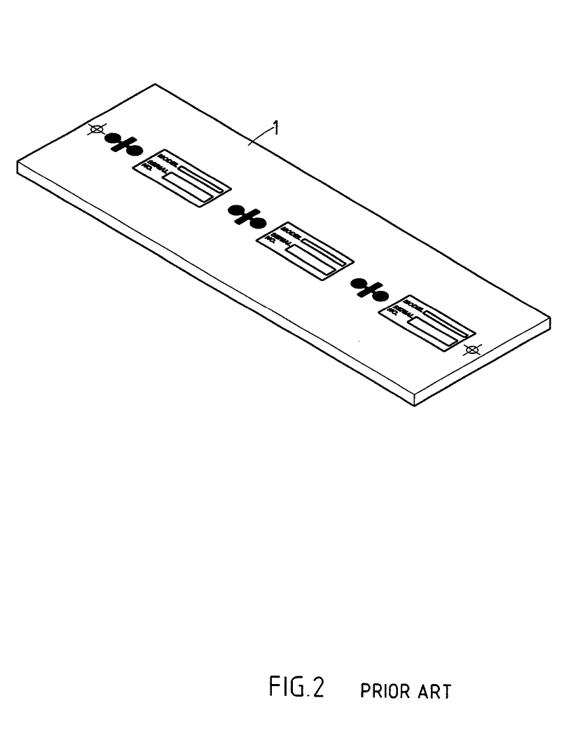

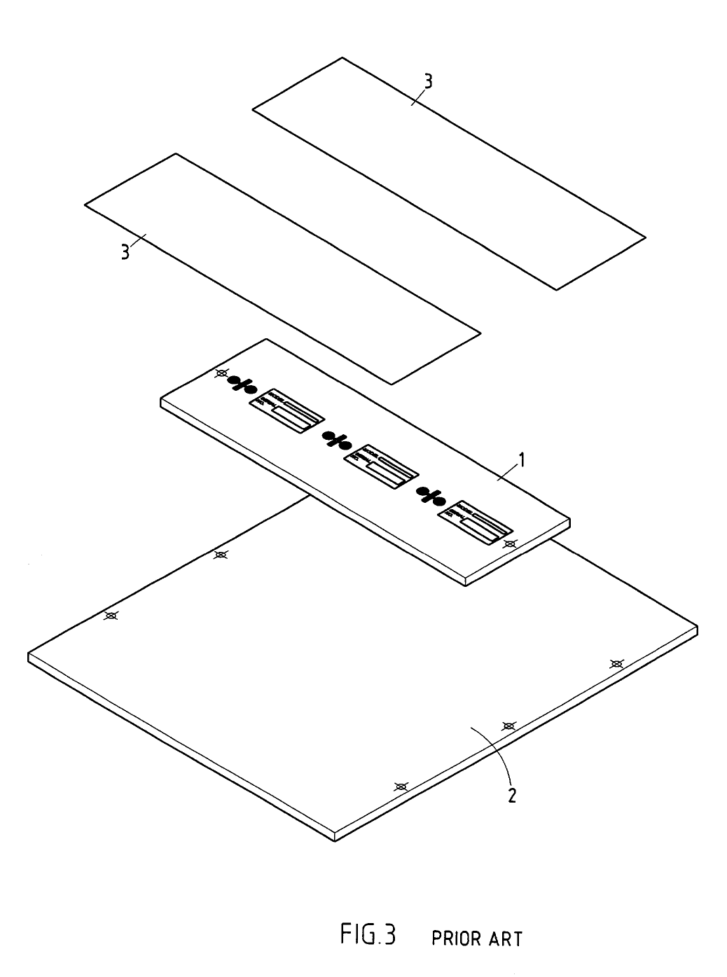

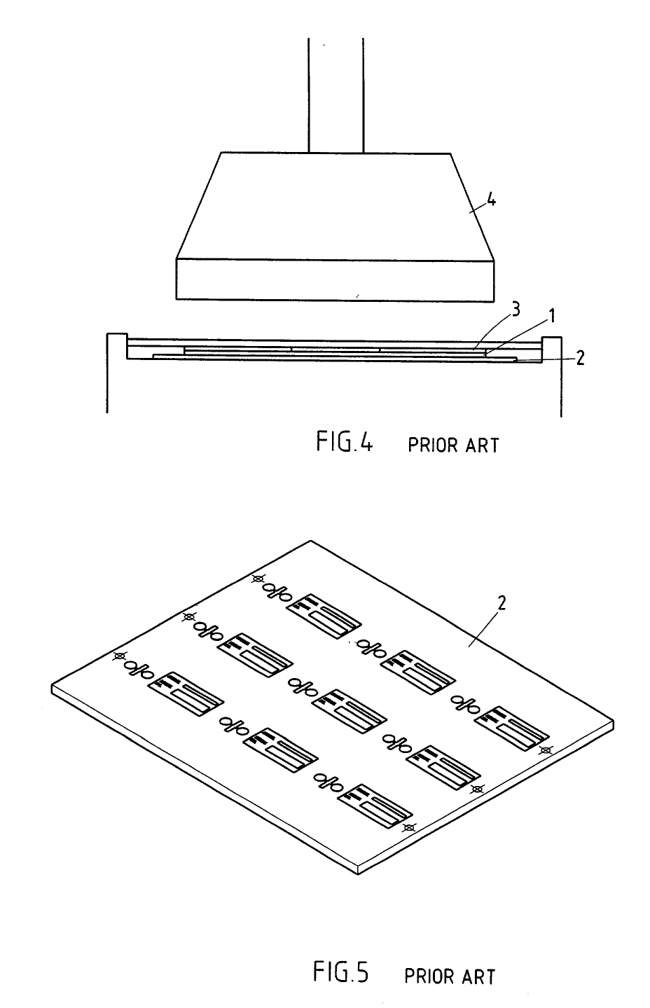

### DETAILED DESCRIPTION OF THE INVENTION

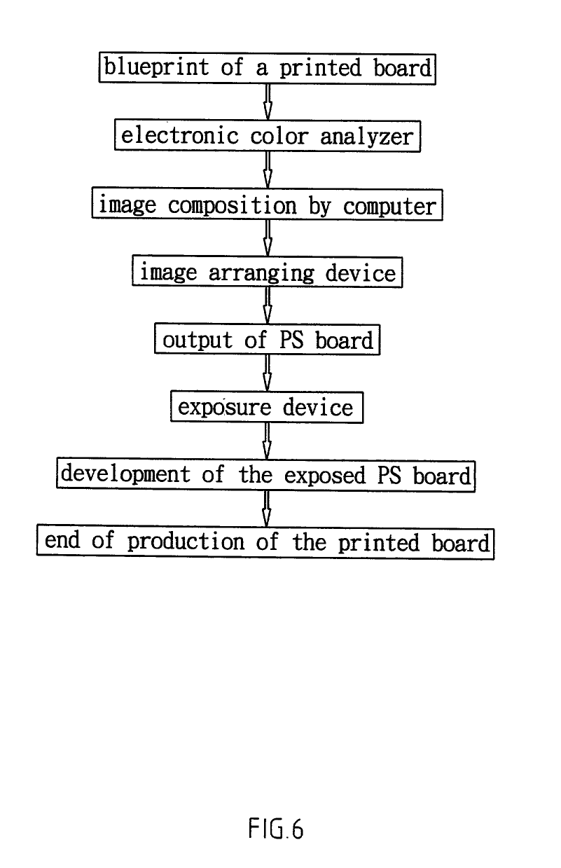

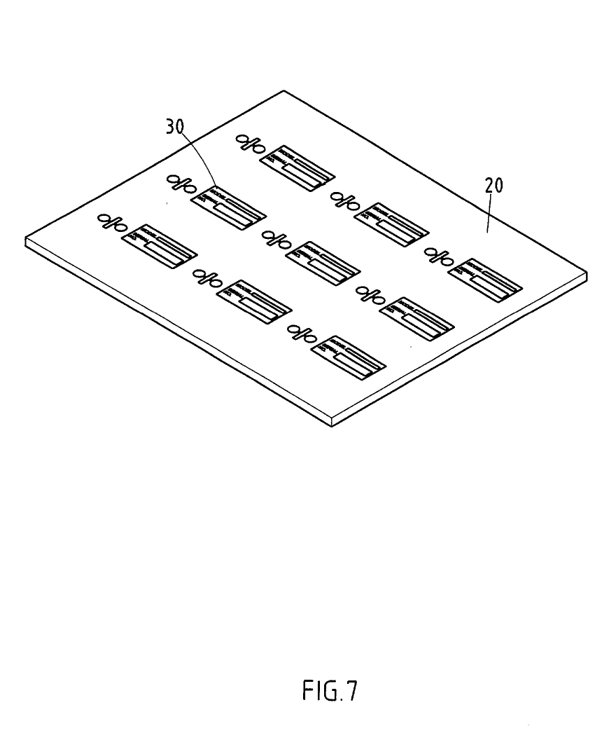

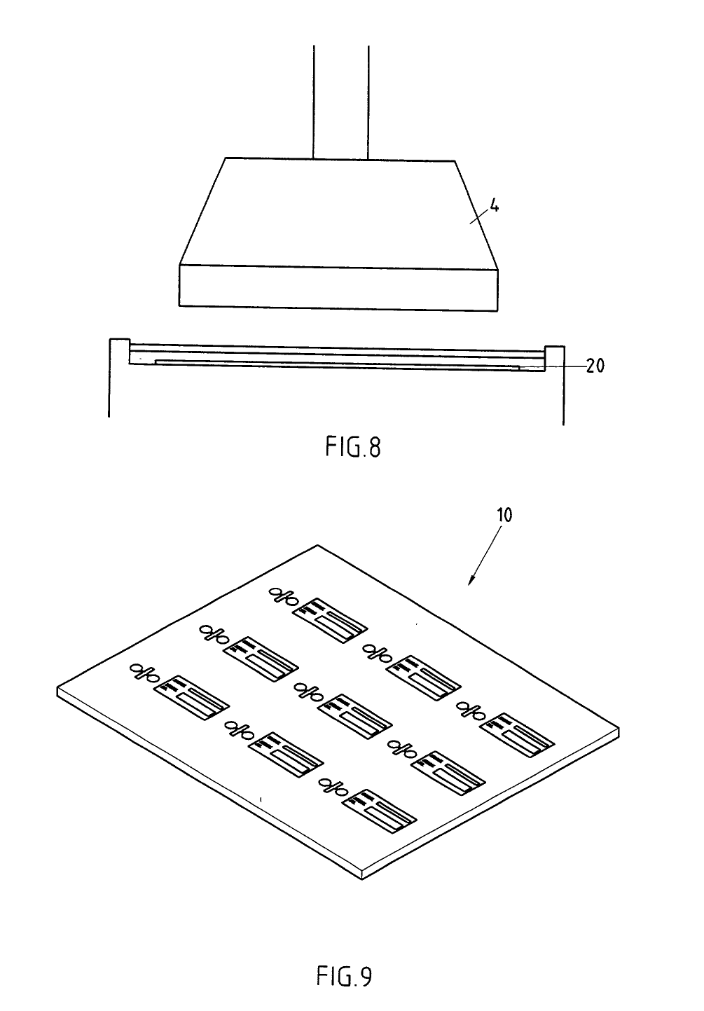

As shown in FIGS. 6-9, a method embodied in the present invention is designed to fabricate a printed board 10 and is composed of a first step in which a blueprint is fed into an electronic color analyzer. Thereafter, an image composition is brought about by a computer which is connected to an image arranging device such that the image composition command is transferred from the computer to the image arranging device. The image arranging device contains a PS board 20 and a photoresist agent 30. The photoresist agent 30 is coated by the image arranging device on the surface of the PS board 20 in accordance with the image composition. In other words, the coating of the photoresist agent 30 is patterned according to the image composition. The coated PS board 20 is then transferred to an exposure device 4 in which the exposure process of the coated PS board 20 is carried out. The exposed PS board 20 is subsequently developed such that the image is formed on the coated area of the surface of the PS board 20.

The method of the present invention is relatively more efficient and cost-effective than the prior art method by virtue of the fact that the method of the present invention is free of the expensive process of making the negative, and that the method of the present invention does not involve the time-consuming assignment of the focus holes of the negative and the PS board, and further that the method of the present invention makes use of the photoresist agent in place of the photomask piece of the prior art method.

I claim:

1. A method of fabricating a printed board, said method comprising the step of:
(a) feeding a blueprint of the printed board into an electronic color analyzer;
(b) composing images of the blueprint by a computer;
(c) arranging images by an image arranging device;
(d) feeding a PS board into the image arranging device;
(e) providing the surface of the PS board with a coating of a photoresist agent by the image arranging device, with the coating being patterned in accordance with the image composition;
(f) exposing the coated PS board in an exposure device; and
(g) developing the exposed PS board.
